(19) United States
(12) Patent Application Publication
(10) Pub. No.: US 2015/0062821 A1
(43) Pub. Date: Mar. 5, 2015

(54) Cooling Structure for Electronic Circuit Board, and Electronic Device Using the Same

(71) Applicant: NEC CORPORATION, Tokyo (JP)

(72) Inventors: Minoru Yoshikawa, Tokyo (JP); Hitoshi Sakamoto, Tokyo (JP); Akira Shoujiguchi, Tokyo (JP); Masaki Chiba, Tokyo (JP); Kenichi Inaba, Tokyo (JP); Arihiro Matsunaga, Tokyo (JP)

(73) Assignee: NEC Corporation, Tokyo (JP)

(21) Appl. No.: 14/385,754

(22) PCT Filed: Mar. 14, 2013
(86) PCT No.: PCT/JP2013/001715

§ 371 Date: Sep. 16, 2014

(30) Foreign Application Priority Data
Mar. 22, 2012 (JP) 2012-066078

(51) Int. Cl. H05K 1/02; H05K 7/20

(52) U.S. Cl. CPC H05K 1/0203; H05K 7/20318; H05K 7/20309; H05K 7/20327
USPC 361/700

(57) ABSTRACT

The size of an electronic device using a cooling structure for an electronic circuit board is increased when using a heating element with a large amount of heat generation, therefore, a cooling structure for an electronic circuit board according to an exemplary aspect of the present invention includes an evaporator with an evaporation container storing a refrigerant; a condenser condensing and liquefying a vapor-phase refrigerant vaporized in the evaporator and radiating heat; and a pipe connecting the evaporator to the condenser, wherein the evaporator includes a heat receiving area, on one side of the evaporation container, thermally connecting to a heating element disposed on the electronic circuit board, and a plurality of flow path plates, in an area including the heat receiving area, extending in the direction parallel to the electronic circuit board; and a vapor-liquid interface of the refrigerant is positioned above or at the level of a lower end and below an upper end of the heat receiving area in the vertical direction, in the arrangement condition that the drawing direction of the flow path plates is approximately parallel to the vertical direction.

### TECHNICAL FIELD

The present invention relates to cooling structures for electronic circuit boards to be plugged into a motherboard of an electronic device and, in particular, to a cooling structure for an electronic circuit board, and an electronic device using the same employing an ebullient cooling system in which heat transport and heat radiation are performed by a phase-change cycle of vaporization and condensation of a refrigerant.

### BACKGROUND ART

In electronic equipment such as a computer, various types of electronic circuit boards, which are called an expansion card or an expansion board, are plugged into slots provided on a motherboard to extend and enhance its functions. High performance computing (HPC) has been developed in recent years, in which a plurality of graphics processing unit (GPU) boards, each of which includes a GPU of a type of processor, are plugged into slots on a motherboard.

With regard to an electronic circuit board on which a high performance processor and the like are mounted, electronic components such as a processor and a memory element generate a large amount of heat. Since the increase in operation temperature causes the decline in the performance of a processor and the like, it is necessary to cool the electronic components. An example of cooling structures for such an electronic circuit board is described in Patent Literature 1.

The cooling structure for an electronic circuit board described in Patent Literature 1 includes an augmented heat removal system that includes a fan provided for a GPU on a card, heat sinks for removal of heat from memory chips, and a flow directing device. The fan is a vertical blower with an axis perpendicular to both the heat sinks and the GPU. The flow directing device has a top with an aperture and an outer edge, and a housing for mounting the fan and diverting airflow along the card.

The configuration mentioned above enables the air flow provided by the fan and the flow directing device to be drawn in perpendicularly towards the GPU and redirected by the flow directing device towards other components to be cooled, specifically heat sinks, and in turn to cool the plurality of memory chips. It is said that the cooling structure for the electronic circuit board described in Patent Literature 1 provides air flow along various heat generating components to cool the components to or within a specified temperature or temperature range.

### CITATION LIST

### Patent Literature

### [PTL 1]

Japanese Patent Application Laid-open Publication No. 2008-235932 (Paragraphs [0019] to [0027] and FIGS. 3 to 5)

### SUMMARY OF INVENTION

### Technical Problem

The cooling structure for the electronic circuit board described in Patent Literature 1 mentioned above requires an additional height to draw cooling air into the fan in addition to physical heights of the electronic components such as a GPU and a memory chip, the fan, and the heat sink in order to cool the electronic circuit board suitably. Accordingly, the cooling structure for the electronic circuit board described in Patent Literature 1 has a problem that the occupied space larger than the cooling structure is required.

FIGS. 7A and 7B illustrate a configuration of a related electronic device using a heat sink as a cooling structure for an electronic circuit board on which a GPU and the like are mounted. FIG. 7A is an elevation view of the related electronic device 500 and FIG. 7B is a top view of the related electronic device 500. It is necessary in the related electronic device 500 to attach a heat sink 530 to a whole surface of a slot card board 520 as illustrated in the figures when a heating element 510 generating a large amount of heat, such as a GPU, is mounted. Additionally, because the cooling performance is insufficient by this, there is a need to extend the length of heat radiation fins 532 in the heat sink 530 as illustrated on the right-hand side of FIG. 8 in order to enlarge an area of the heat radiation fins 532. The slot card board 520 is plugged into a slot 542 on a motherboard 540 with a connector 522. A pitch of the slots 542 is equal to 0.8 inches (20.32 mm) in the PCI (peripheral component interconnect) standard. Accordingly, if the length of the heat radiation fins 532 is extended, the heat radiation fins 532 occupy two times as much space as the volume occupied by one of the slot card board 520 on the motherboard 540. That is to say, there has been a problem that the package density is decreased and the device size is increased in the related electronic device 500 using a heat sink as a cooling structure for electronic circuit boards.

Thus, the related cooling structure for electronic circuit boards has a problem that using a heating element with a large amount of heat generation makes an electronic device grow in size.

The object of the present invention is to provide a cooling structure for an electronic circuit board, and an electronic device using the same that solve the problem mentioned above that the size of an electronic device using a cooling structure for an electronic circuit board is increased when using a heating element with a large amount of heat generation.

### Solution to Problem

A cooling structure for an electronic circuit board according to an exemplary aspect of the present invention includes an evaporator with an evaporation container storing a refrigerant; a condenser condensing and liquefying a vapor-phase refrigerant vaporized in the evaporator and radiating heat; and a pipe connecting the evaporator to the condenser, wherein the evaporator includes a heat receiving area, on one side of the evaporation container, thermally connecting to a heating element disposed on the electronic circuit board, and a plurality of flow path plates, in an area including the heat receiving area, extending in the direction parallel to the electronic circuit board; and a vapor-liquid interface of the refrigerant is positioned above or at the level of a lower end and below an upper end of the heat receiving area in the vertical direction, in the arrangement condition that the drawing direction of the flow path plates is approximately parallel to the vertical direction.

An electronic device using a cooling structure for an electronic circuit board according to an exemplary aspect of the present invention includes a heating element; an electronic circuit board on which the heating element is disposed; and a cooling structure for the electronic circuit board, wherein the cooling structure for the electronic circuit board includes an evaporator with an evaporation container storing a refrigerant; a condenser condensing and liquefying a vapor-phase refrigerant vaporized in the evaporator and radiating heat; and a pipe connecting the evaporator to the condenser, wherein the evaporator includes a heat receiving area, on one side of the evaporation container, thermally connecting to the heating element disposed on the electronic circuit board, and a plurality of flow path plates, in an area including the heat receiving area, extending in the direction parallel to the electronic circuit board; and a vapor-liquid interface of the refrigerant is positioned above or at the level of a lower end and below an upper end of the heat receiving area in the vertical direction, in the arrangement condition that the drawing direction of the flow path plates is approximately parallel to the vertical direction.

### Advantageous Effects of Invention

According to the cooling structure for an electronic circuit board of the present invention, it is possible to avoid the increase in size of an electronic device even when used for a heating element with a large amount of heat generation.

### BRIEF DESCRIPTION OF DRAWINGS

FIG. 1A is a diagram illustrating a configuration of a cooling structure for an electronic circuit board in accordance with the first exemplary embodiment of the present invention and is a partially perspective elevation view.

FIG. 1B is a diagram illustrating the configuration of the cooling structure for the electronic circuit board in accordance with the first exemplary embodiment of the present invention and is a partially perspective bottom view viewed from the direction indicated by arrow B in FIG. 1A.

FIG. 1C is a diagram illustrating the configuration of the cooling structure for the electronic circuit board in accordance with the first exemplary embodiment of the present invention and is a cross-sectional view taken along the line C-C of FIG. 1A.

FIG. 2 is an elevation view illustrating a configuration of an electronic device using a cooling structure for an electronic circuit board in accordance with the second exemplary embodiment of the present invention.

FIG. 3A is a top view illustrating another configuration of the electronic device using the cooling structure for the electronic circuit board in accordance with the second exemplary embodiment of the present invention.

FIG. 3B is a side view illustrating another configuration of the electronic device using the cooling structure for the electronic circuit board in accordance with the second exemplary embodiment of the present invention.

FIG. 4A is an elevation view illustrating yet another configuration of the electronic device using the cooling structure for the electronic circuit board in accordance with the second exemplary embodiment of the present invention.

FIG. 4B is a side view illustrating yet another configuration of the electronic device using the cooling structure for the electronic circuit board in accordance with the second exemplary embodiment of the present invention.

FIG. 5A is a top view illustrating a configuration of an electronic device using a cooling structure for an electronic circuit board in accordance with the third exemplary embodiment of the present invention.

FIG. 5B is a side view illustrating the configuration of the electronic device using the cooling structure for the electronic circuit board in accordance with the third exemplary embodiment of the present invention.

FIG. 6 is a top view illustrating another configuration of the electronic device using the cooling structure for the electronic circuit board in accordance with the third exemplary embodiment of the present invention.

FIG. 7A is an elevation view illustrating a configuration of a related electronic device.

FIG. 7B is a top view illustrating the configuration of the related electronic device.

FIG. 8 is a side view illustrating the configuration of the related electronic device.

### DESCRIPTION OF EMBODIMENTS

The exemplary embodiments of the present invention will be described with reference to drawings below.

### The First Exemplary Embodiment

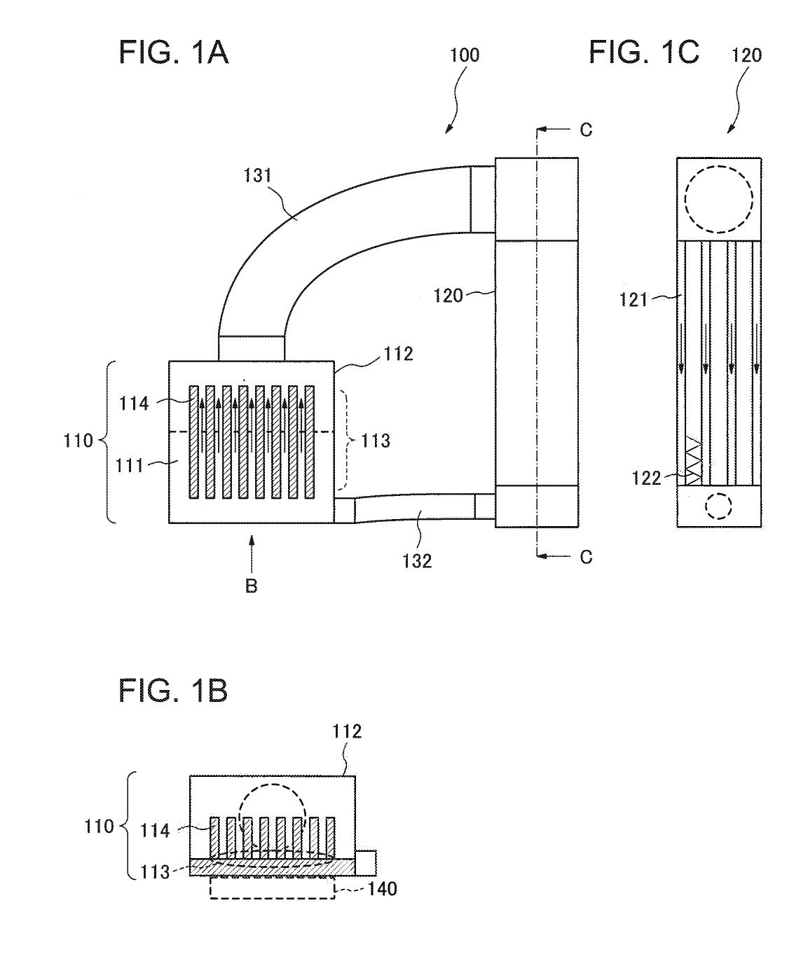

FIGS. 1A, 1B, and 1C are diagrams illustrating the configuration of a cooling structure for an electronic circuit board 100 in accordance with the first exemplary embodiment of the present invention. FIG. 1A is a partially perspective elevation view, FIG. 1B is a partially perspective bottom view viewed from the direction indicated by arrow B in FIG. 1A, and FIG. 1C is a cross-sectional view taken along the line C-C of FIG. 1A.

The cooling structure for an electronic circuit board 100 includes an evaporator 110 with an evaporation container 112 storing a refrigerant 111, and a condenser 120 condensing and liquefying a vapor-phase refrigerant vaporized in the evaporator 110 and radiating heat. The evaporator 110 and the condenser 120 are connected by a vapor pipe 131 and a liquid pipe 132 as a pipe 130. The evaporator 110 includes a heat receiving area 113, on one side of the evaporation container 112, thermally connecting to a heating element 140 disposed on the electronic circuit board, and a plurality of flow path plates 114, in the area including the heat receiving area 113, extending in the direction parallel to the electronic circuit board.

The vapor-liquid interface of the refrigerant is positioned above or at the level of the lower end of the heat receiving area 113 and below the upper end of the heat receiving area 113 in the vertical direction, in the arrangement condition that the drawing direction of the flow path plates 114 is approximately parallel to the vertical direction as illustrated in FIG. 1A. The vapor-liquid interface of the refrigerant means an interface between the refrigerant in liquid state and the refrigerant in vapor state, and is represented by the dotted line on the hatching region in the evaporation container 112 in FIG. 1A.

It is possible to keep the pressure within the evaporator 110 equal to a saturated vapor pressure of the refrigerant constantly by using a low-boiling material as the refrigerant and evacuating the evaporator 110 after having injected the refrigerant into it. It is possible to use as the refrigerant a low-boiling refrigerant such as hydrofluorocarbon and hydrofluoroether which are insulating and inactive materials, for example. As the materials composing the evaporator 110 and the condenser 120, it is possible to use the metal having an excellent thermal conductive property such as aluminum and copper. It is possible to use for the pipe 130 a pipe made of resin such as rubber whose inner surface is coated with metal, for example. The flow path plate 114 is formed by using the metal having an excellent thermal conductive property such as aluminum and copper, and can have a fin shape composed of a plurality of thin plates as illustrated in FIGS. 1A and 1B.

Next, the operation of the cooling structure for an electronic circuit board 100 in accordance with the present exemplary embodiment will be described in detail. The cooling structure for an electronic circuit board 100 is used disposing a heating element 140 such as a central processing unit (CPU) on the side of the evaporation container 112 composing the evaporator 110, thermally connected to the evaporator 110. The heat from the heating element 140 is conducted to the refrigerant 111 through the evaporation container 112, so that the refrigerant 111 vaporizes. At this time, since the heat from the heating element is drawn by the refrigerant as vaporization heat, the increase in temperature of the heating element is suppressed.

The refrigerant vapor evaporated in the evaporator 110 flows into the condenser 120 through the vapor pipe 131. The refrigerant vapor releases heat in the condenser 120, condenses and liquefies. As mentioned above, the cooling structure for an electronic circuit board 100 is configured to employ the ebullient cooling system in which heat transport and heat radiation are performed by a cycle of vaporization and condensation of the refrigerant.

The cooling structure for an electronic circuit board 100 in accordance with the present exemplary embodiment is configured to include a plurality of flow path plates 114 extending in the direction parallel to the electronic circuit board in a region including the heat receiving area 113 of the evaporation container 112. Flow paths of the refrigerant are formed between the flow path plates 114, and a vapor-liquid two-phase flow of the refrigerant arises in the heat receiving area below the vapor-liquid interface of the refrigerant in the vertical direction. Here, the vapor-liquid two-phase flow is defined as flowing with two phases of a vapor phase and a liquid phase being mixed. Since the vapor-liquid two-phase flow of the refrigerant rises with bubbles of the refrigerant taking in the liquid-phase refrigerant around them, the liquid-phase refrigerant reaches the heat receiving area located above the vapor-liquid interface of the refrigerant in the vertical direction. Accordingly, it is possible to cool the entire heat receiving area 113 by means of the phase change of the refrigerant even though the vapor-liquid interface of the refrigerant is located below the upper end of the heat receiving area 113 in the vertical direction.

A distance between the flow path plates 114 is determined by the condition under which a vapor-liquid two-phase flow arises. Specifically, the distance can be determined based on physical property values of the refrigerant such as surface tension, molecular weight, and kinetic viscosity of the refrigerant. When hydrofluorocarbon, hydrofluoroether, or the like mentioned above is used as the refrigerant, the distance between the flow path plates 114 can preferably take a range of values from approximately 0.5 mm to approximately 2 mm.

Since it is possible to lower the vapor-liquid interface of the refrigerant in the cooling structure for an electronic circuit board 100 in accordance with the present exemplary embodiment as mentioned above, it is possible to enlarge the space occupied by the vapor-phase refrigerant without increasing the volume of the evaporation container 112. As a result, even when used for a heating element with a large amount of heat generation, the elevation in the internal pressure of the vapor-phase refrigerant is suppressed, and it does not result in deterioration in the cooling performance due to an elevation of the boiling point of the refrigerant. That is to say, according to the cooling structure for an electronic circuit board 100 of the present exemplary embodiment, it is possible to avoid the increase in size of an electronic device even when used for a heating element with a large amount of heat generation.

It is acceptable for the condenser 120 to be configured to include a plurality of condensation flow paths 121 extending in the direction approximately parallel to the drawing direction of the flow path plates 114, and heat radiation plates (heat radiation fins) 122 between the condensation flow paths 121. Since the plurality of condensation flow paths 121 makes it possible to reduce the flow resistance of the refrigerant vapor (vapor-phase refrigerant) in the condenser 120, it is possible to suppress the elevation in the internal pressure of the vapor-phase refrigerant. Since the condensation heat-transfer efficiency is improved because of increasing the condensation area, it is possible to improve the cooling performance.

The condenser 120 can be configured in which its lower end in the vertical direction is located on roughly the same level as the lower end in the vertical direction of the evaporator 110 in the arrangement state that the drawing direction of the flow path plates 114 is nearly parallel to the vertical direction as illustrated in FIG. 1A. That is to say, it is possible to dispose the condenser 120 on nearly the same level as the evaporator 110. This is because according to the cooling structure for an electronic circuit 100 of the present exemplary embodiment, it is unnecessary to fill the entirety of the heat receiving area 113 with liquid-phase refrigerant and it is possible to lower the vapor-liquid interface of the refrigerant in the vertical direction. This makes it possible to further miniaturize an electronic device using the cooling structure for an electronic circuit board 100.

### The Second Exemplary Embodiment

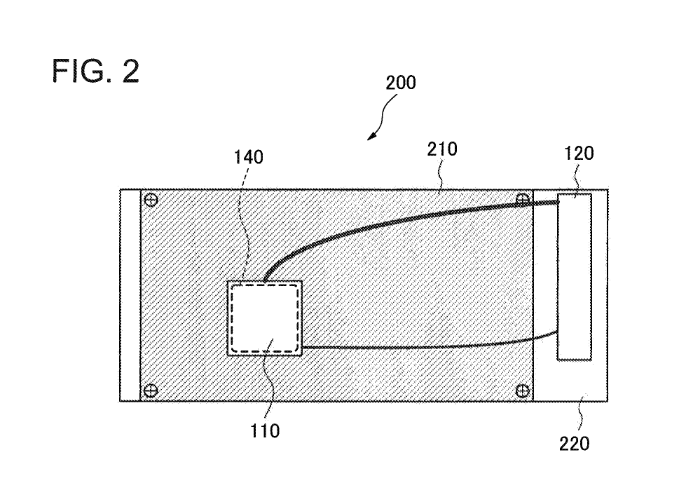

Next, the second exemplary embodiment of the present invention will be described. FIG. 2 is an elevation view illustrating a configuration of an electronic device 200 using a cooling structure for an electronic circuit board in accordance with the second exemplary embodiment of the present invention. The electronic device 200 using the cooling structure for an electronic circuit board includes a heating element 140, an electronic circuit board 210 on which the heating element 140 is disposed, and the cooling structure for an electronic circuit board 100 including the evaporator 110 and the condenser 120.

It is possible to use, as the heating element 140, an LSI (large scale integration) element, especially a micro processing unit (MPU), a graphics processing unit (GPU) or the like which generates a large amount of heat. It is possible to use, as the electronic circuit board 210, an expansion card, an expansion board or the like which is plugged into a slot set on a motherboard with the surface of the board parallel to the vertical direction. Specific examples include a PCI card, a slot card, and a GPU board, for example. The configuration of the cooling structure for an electronic circuit board 100 is the same as that according to the first exemplary embodiment, and therefore, the description of the configuration will be omitted.

As illustrated in FIG. 2, the evaporator 110 composing the cooling structure for an electronic circuit board 100 is disposed on the electronic circuit board 210 sandwiching the heating element 140. A chassis 220 housing the electronic circuit board 210 and the cooling structure for an electronic circuit board 100 is included. The condenser 120 composing the cooling structure for an electronic circuit board 100 and the electronic circuit board 210 can be configured to be connected to the chassis 220. This configuration makes it possible to transport the heat generation from the heating element 140 to the condenser 120 fixed on the chassis 220 outside the electronic circuit board 210 by phase-change cooling. Accordingly, since the condenser 120 can be configured without being limited by the size, the arrangement and the like of the electronic circuit board 210, it is possible to improve the cooling performance.

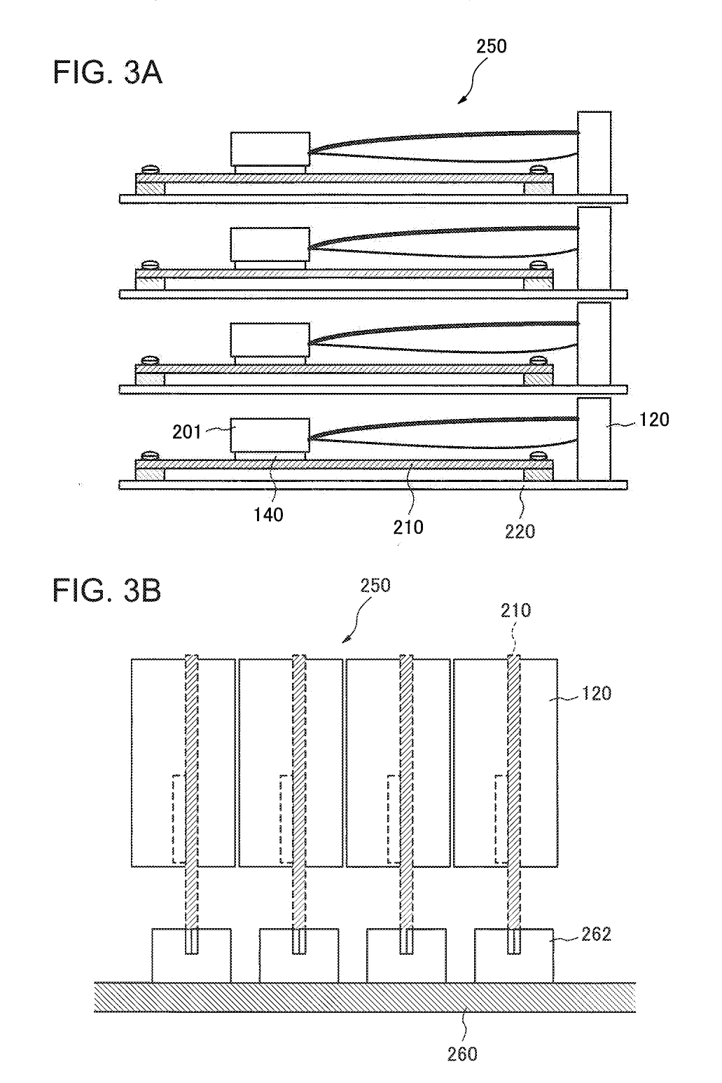

FIGS. 3A and 3B illustrate configurations of an electronic device 250 including a plurality of electronic circuit boards 210 and using the cooling structure for an electronic circuit board. FIG. 3A is a top view and FIG. 3B is a side view. The electronic device 250 using the cooling structure for an electronic circuit board is configured to include a motherboard 260 on which a plurality of electronic circuit boards 210 are mounted at a predetermined alignment interval (slot pitch). The plurality of electronic circuit boards 210 are disposed on the motherboard 260 in the state that the drawing direction of the flow path plates 114 composing the evaporator 110 is nearly parallel to the vertical direction. That is to say, the electronic circuit board 210 is plugged with its principal surface parallel to the vertical direction. Specifically, for example, the electronic circuit board 210 is plugged through a slot 262 provided for the motherboard 260. The electronic circuit board 210 is fixed to a boss provided for the chassis 220 by using a screw or the like.

By the configuration described above, the condenser 120 composing the cooling structure for an electronic circuit board 100 can be configured so that the width in the direction perpendicular to the electronic circuit board 210 may be extended to a width nearly equal to the alignment interval (slot pitch). In addition, it is possible to extend the heat radiation plate 122 between the condensation flow paths 121 composing the condenser 120 to a width nearly equal to the alignment interval (slot pitch). Since a crossflow heat exchanger is configured by setting the heat radiation plates 122, the heat radiation capability can be improved as compared with a parallel-flow heat sink using the sensible heat.

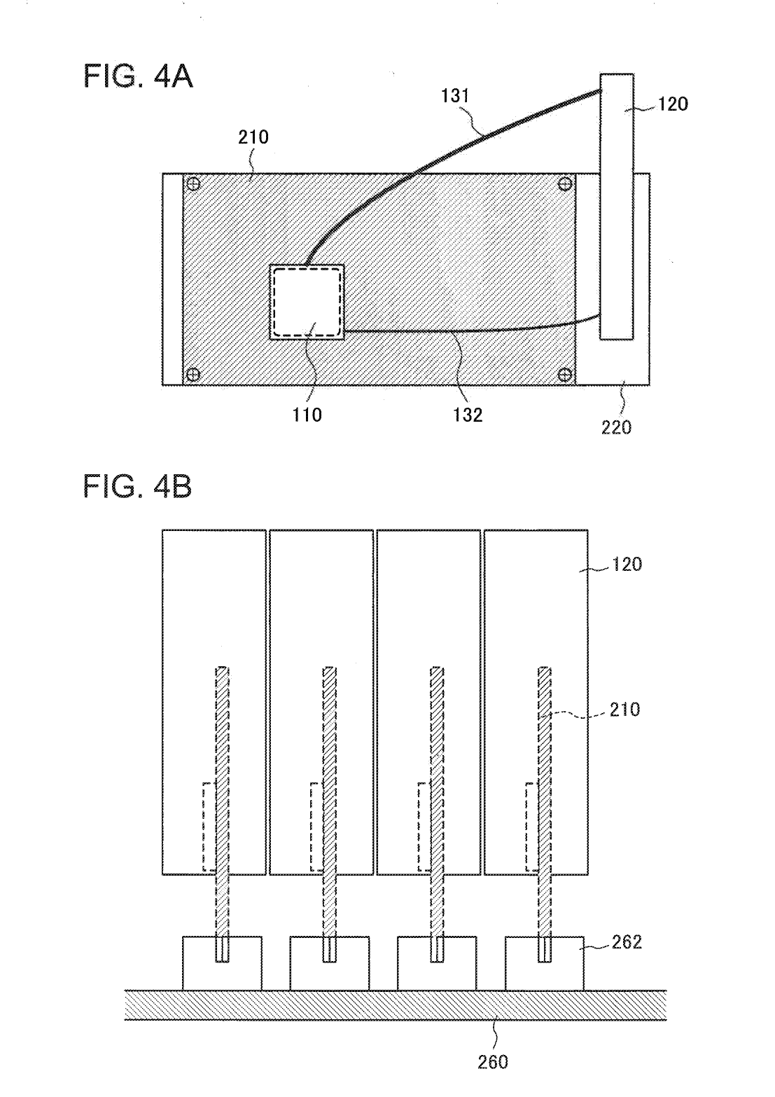

As illustrated in FIGS. 4A and 4B, it is also acceptable for the condenser 120 to be configured so that the upper end of the condenser 120 in the vertical direction may be above the level of the upper end of the electronic circuit board 210 in the vertical direction, in the arrangement state that the drawing direction of the flow path plates 114 is nearly parallel to the vertical direction. This configuration makes it possible to increase the inner volume of the condenser 120 and to further improve the heat radiation capability.

As described above, according to the electronic device using the cooling structure for an electronic circuit board of the present exemplary embodiment, by adopting the cooling structure for an electronic circuit board 100 according to the present exemplary embodiment, it is possible to avoid the increase in size of the electronic device even when used for a heating element with a large amount of heat generation. In addition, since the condenser 120 can be configured without being limited by the size, the arrangement and the like of the electronic circuit board 210, it is possible to improve the cooling performance.

### The Third Exemplary Embodiment

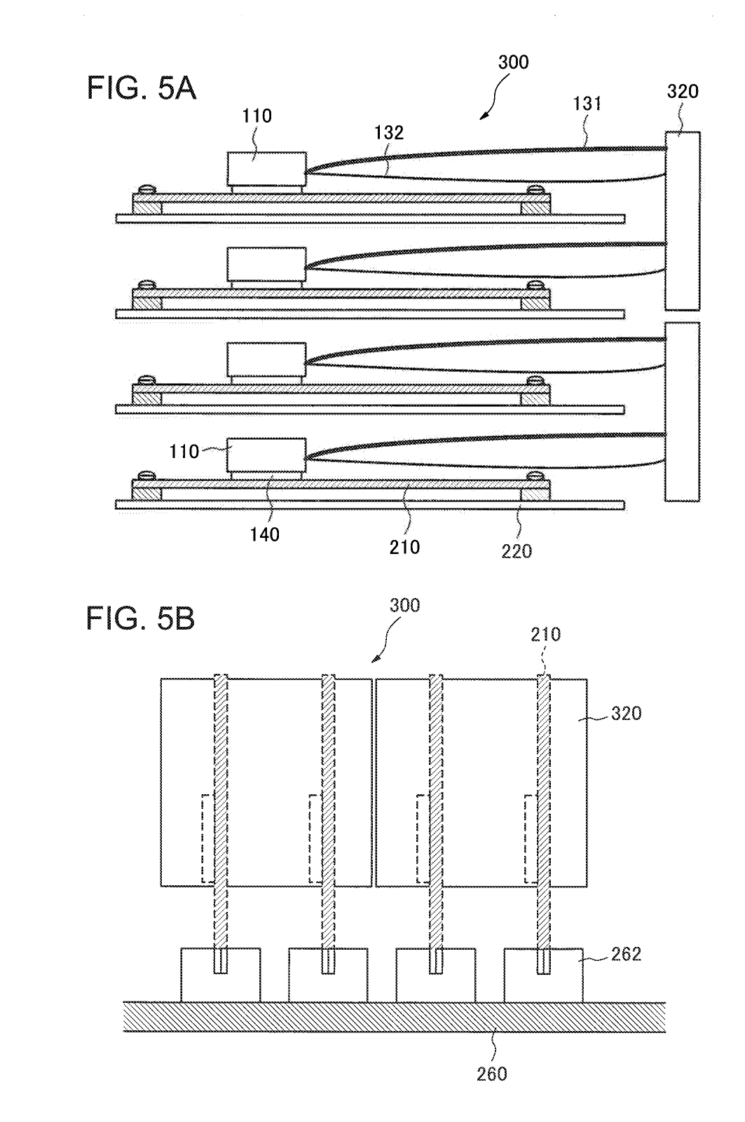

Next, the third exemplary embodiment of the present invention will be described. FIGS. 5A and 5B illustrate a configuration of an electronic device 300 using the cooling structure for an electronic circuit board according to the third exemplary embodiment of the present invention, and FIG. 5A is a top view and FIG. 5B is a side view. The electronic device 300 using the cooling structure for an electronic circuit board is configured to include a motherboard 260 on which a plurality of electronic circuit boards 210 are mounted at a predetermined alignment interval (slot pitch). The plurality of electronic circuit boards 210 are disposed on the motherboard 260 in the state that the drawing direction of the flow path plates 114 composing the evaporator 110 is nearly parallel to the vertical direction. That is to say, the electronic circuit board 210 is plugged with its principal surface parallel to the vertical direction.

The electronic device 300 using the cooling structure for an electronic circuit board includes a heating element 140, an electronic circuit board 210 on which the heating element 140 is disposed, and the cooling structure for an electronic circuit board 100 including the evaporator 110 and a condenser 320. The configuration and the operation of the cooling structure for an electronic circuit board 100 are the same as those according to the first exemplary embodiment except the configuration of the condenser 320 described below, and therefore, the description of the same part will be omitted.

As illustrated in FIGS. 5A and 5B, the electronic device 300 using the cooling structure for an electronic circuit board is configured so that the width of the condenser 320 in the direction perpendicular to the electronic circuit board 210 may be larger than the alignment interval on the motherboard 260. That is to say, the electronic device 300 using the cooling structure for an electronic circuit board is configured to connect a plurality of electronic circuit boards 210 such as slot cards to a single condenser 320 collectively. The vapor pipes 131 and the liquid pipes 132 as the pipe connect more than one evaporator 110 to one of the condenser 320.

Since the configuration described above makes it possible to increase the volume of the condenser 320 even when the electronic circuit boards 210 are disposed on the motherboard 260 at a unit of alignment interval, it is possible to improve the cooling performance of the cooling structure for an electronic circuit board 100. That is to say, since the interference between the adjacent condensers 320 can be reduced and accordingly the heat radiation area of the condenser 320 can be increased, it is possible to further improve the cooling performance.

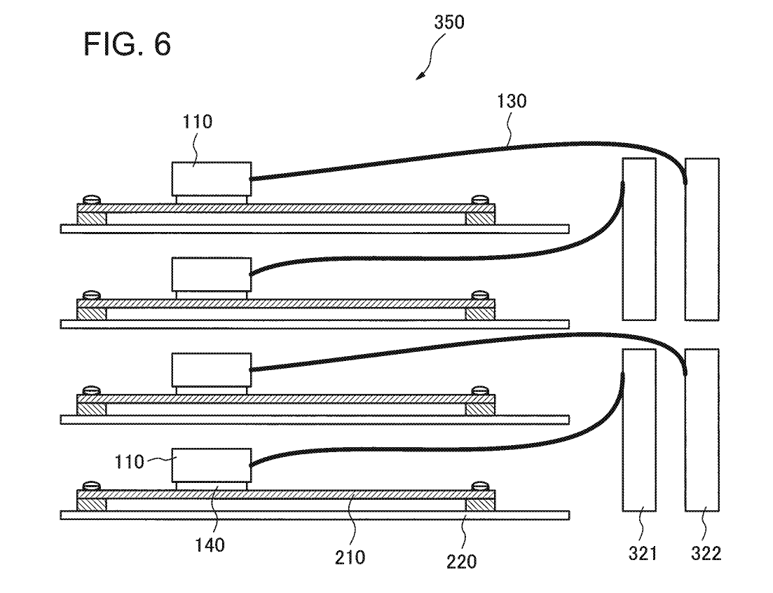

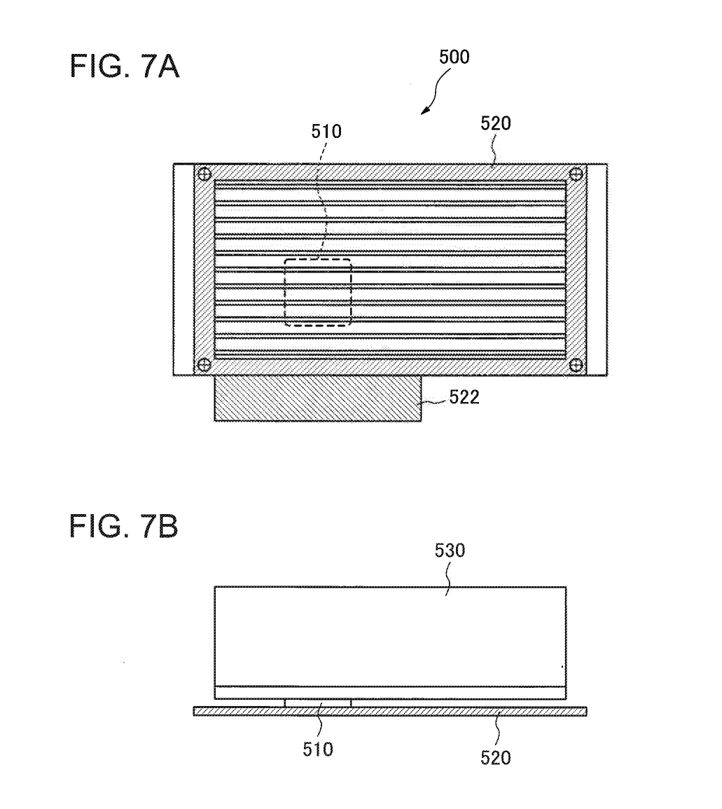

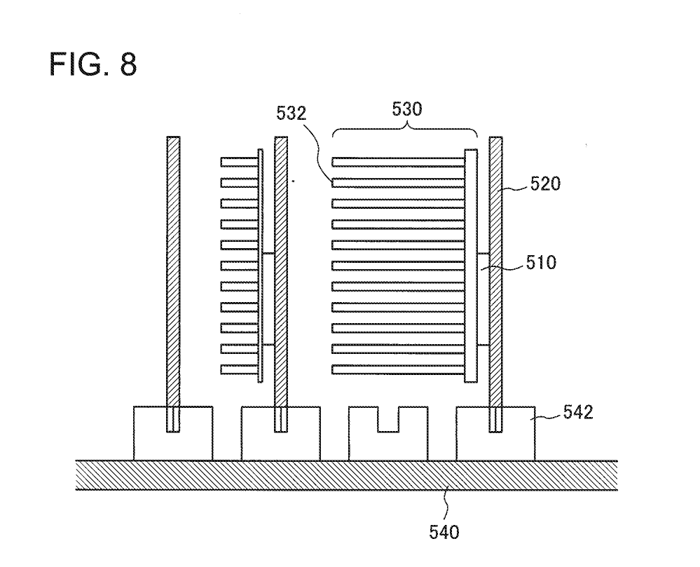

The electronic device 300 using the cooling structure for an electronic circuit board is configured to connect more than one evaporator 110 to one of the condenser 320 through the vapor pipes 131 and the liquid pipes 132. The configuration is not limited to this, however, as illustrated in FIG. 6, it can be also configured to dispose the condensers 320 in multistage and for the pipe 130 to connect the evaporator 110 to the condenser 320 one-on-one. That is to say, an electronic device 350 using the cooling structure for an electronic circuit board illustrated in FIG. 6 includes a plurality of evaporators 110 and a plurality of condensers 320 including at least a first condenser 321 and a second condenser 322. The second condenser 322 is disposed to be an extension of the straight line connecting one of the evaporators 110 to the first condenser 321. In other words, the first condenser 321 and the second condenser 322 are disposed in multistage in the direction of a cooling air flow.

Since this also makes it possible to be configured so that the condenser 320 may have a width larger than the alignment interval on the motherboard 260, it is possible to increase the volume of the condenser 320. Therefore, since it is possible to suppress the elevation in the internal pressure of the cooling structure for an electronic circuit board even when the electronic circuit boards 210 are disposed on the motherboard 260 at a unit of alignment interval, it is possible to improve the cooling performance.

As described above, according to the electronic device using the cooling structure for an electronic circuit board of the present exemplary embodiment, by adopting the cooling structure for an electronic circuit board 100 according to the present exemplary embodiment, it is possible to avoid the increase in size of the electronic device even when used for a heating element with a large amount of heat generation. In addition, since the condenser 320 can be configured without being limited by the size, the arrangement and the like of the electronic circuit board 210, it is possible to improve the cooling performance.

The present invention is not limited to the aforementioned exemplary embodiments. Various modifications can be made therein within the scope of the present invention as defined by the claims, and obviously, such modifications are included in the scope of the present invention.

This application is based upon and claims the benefit of priority from Japanese Patent Application No. 2012-066078, filed on Mar. 22, 2012, the disclosure of which is incorporated herein in its entirety by reference.

### REFERENCE SIGNS LIST

100 Cooling structure for an electronic circuit board
110 Evaporator
111 Refrigerant
112 Evaporation container
113 Heat receiving area
114 Flow path plate
120, 320 Condenser
121 Condensation flow path
122 Heat radiation plate
130 Pipe
131 Vapor pipe
132 Fluid pipe
140 Heating element
200, 250, 300, 350 Electronic device using cooling structure for an electronic circuit board
210 Electronic circuit board
220 Chassis
260 Motherboard
262 Slot
321 First condenser
322 Second condenser
500 Electronic device
510 Heating element
520 Slot card board
522 Connector
530 Heat sink
532 Heat radiation fin
540 Motherboard
542 Slot

1. A cooling structure for an electronic circuit board, comprising:
an evaporator with an evaporation container storing a refrigerant;
a condenser condensing and liquefying a vapor-phase refrigerant vaporized in the evaporator and radiating heat; and
a pipe connecting the evaporator to the condenser,
wherein the evaporator comprises a heat receiving area, on one side of the evaporation container, thermally connecting to a heating element disposed on the electronic circuit board, and a plurality of flow path plates, in an area comprising the heat receiving area, extending in the direction parallel to the electronic circuit board; and
a vapor-liquid interface of the refrigerant is positioned above or at the level of a lower end and below an upper end of the heat receiving area in the vertical direction, in the arrangement condition that the drawing direction of the flow path plates is approximately parallel to the vertical direction.

2. The cooling structure for an electronic circuit board according to claim 1,
wherein the condenser comprises a plurality of condensation flow paths extending in the direction approximately parallel to the drawing direction of the flow path plates, and a heat radiation plate between the condensation flow paths.

3. The cooling structure for an electronic circuit board according to claim 1,
wherein a lower end in the vertical direction of the condenser is located on roughly the same level as a lower end in the vertical direction of the evaporator in the arrangement state that the drawing direction of the flow path plate is nearly parallel to the vertical direction.

4. An electronic device using a cooling structure for an electronic circuit board, comprising:
a heating element;
an electronic circuit board on which the heating element is disposed; and
a cooling structure for the electronic circuit board,
wherein the cooling structure for the electronic circuit board comprises an evaporator with an evaporation container storing a refrigerant;
a condenser condensing and liquefying a vapor-phase refrigerant vaporized in the evaporator and radiating heat; and
a pipe connecting the evaporator to the condenser,
wherein the evaporator comprises a heat receiving area, on one side of the evaporation container, thermally connecting to the heating element disposed on the electronic circuit board, and a plurality of flow path plates, in an area comprising the heat receiving area, extending in the direction parallel to the electronic circuit board; and
a vapor-liquid interface of the refrigerant is positioned above or at the level of a lower end and below an upper end of the heat receiving area in the vertical direction, in the arrangement condition that the drawing direction of the flow path plates is approximately parallel to the vertical direction.

5. The electronic device using the cooling structure for an electronic circuit board according to claim 4,
wherein the condenser comprises a plurality of condensation flow paths extending in the direction approximately parallel to the drawing direction of the flow path plates, and a heat radiation plate between the condensation flow paths.

6. The electronic device using the cooling structure for an electronic circuit board according to claim 4,
wherein a lower end in the vertical direction of the condenser is located on roughly the same level as a lower end in the vertical direction of the evaporator in the arrangement state that the drawing direction of the flow path plate is nearly parallel to the vertical direction.

7. The electronic device using the cooling structure for an electronic circuit board according to claim 4, further comprising a chassis housing the electronic circuit board and the cooling structure for the electronic circuit board,
wherein the condenser is connected to the chassis,
the evaporator is disposed on the electronic circuit board sandwiching the heating element, and
the electronic circuit board is connected to the chassis.

8. The electronic device using the cooling structure for an electronic circuit board according to claim 4, further comprising a motherboard on which a plurality of the electronic circuit boards are mounted at a predetermined alignment interval,
wherein the plurality of electronic circuit boards are disposed on the motherboard in the state that the drawing direction of the flow path plates is nearly parallel to the vertical direction,
a width of the condenser in the direction perpendicular to the electronic circuit boards is larger than the alignment interval, and
the pipe connects more than one of the evaporators to one of the condensers.

9. The electronic device using the cooling structure for an electronic circuit board according to claim 4, comprising a plurality of the evaporators, and a plurality of the condensers comprising at least a first condenser and a second condenser,
wherein the second condenser is disposed to be an extension of a straight line connecting one of the evaporators to the first condenser.

10. The electronic device using the cooling structure for an electronic circuit board according to claim 4,
wherein an upper end of the condenser in the vertical direction is above the level of an upper end of the electronic circuit board in the vertical direction, in the arrangement state that the drawing direction of the flow path plates is nearly parallel to the vertical direction.

11. The cooling structure for an electronic circuit board according to claim 2,
wherein a lower end in the vertical direction of the condenser is located on roughly the same level as a lower end in the vertical direction of the evaporator in the arrangement state that the drawing direction of the flow path plate is nearly parallel to the vertical direction.

12. The electronic device using the cooling structure for an electronic circuit board according to claim 5,
wherein a lower end in the vertical direction of the condenser is located on roughly the same level as a lower end in the vertical direction of the evaporator in the arrangement state that the drawing direction of the flow path plate is nearly parallel to the vertical direction.

13. The electronic device using the cooling structure for an electronic circuit board according to claim 5, further comprising a chassis housing the electronic circuit board and the cooling structure for the electronic circuit board,
wherein the condenser is connected to the chassis,
the evaporator is disposed on the electronic circuit board sandwiching the heating element, and
the electronic circuit board is connected to the chassis.

14. The electronic device using the cooling structure for an electronic circuit board according to claim 6, further comprising a chassis housing the electronic circuit board and the cooling structure for the electronic circuit board,
wherein the condenser is connected to the chassis,
the evaporator is disposed on the electronic circuit board sandwiching the heating element, and
the electronic circuit board is connected to the chassis.

15. The electronic device using the cooling structure for an electronic circuit board according to claim 5, further comprising a motherboard on which a plurality of the electronic circuit boards are mounted at a predetermined alignment interval,
wherein the plurality of electronic circuit boards are disposed on the motherboard in the state that the drawing direction of the flow path plates is nearly parallel to the vertical direction,
a width of the condenser in the direction perpendicular to the electronic circuit boards is larger than the alignment interval, and
the pipe connects more than one of the evaporators to one of the condensers.

16. The electronic device using the cooling structure for an electronic circuit board according to claim 6, further comprising a motherboard on which a plurality of the electronic circuit boards are mounted at a predetermined alignment interval,
wherein the plurality of electronic circuit boards are disposed on the motherboard in the state that the drawing direction of the flow path plates is nearly parallel to the vertical direction,
a width of the condenser in the direction perpendicular to the electronic circuit boards is larger than the alignment interval, and
the pipe connects more than one of the evaporators to one of the condensers.

17. The electronic device using the cooling structure for an electronic circuit board according to claim 7, further comprising a motherboard on which a plurality of the electronic circuit boards are mounted at a predetermined alignment interval,
wherein the plurality of electronic circuit boards are disposed on the motherboard in the state that the drawing direction of the flow path plates is nearly parallel to the vertical direction,
a width of the condenser in the direction perpendicular to the electronic circuit boards is larger than the alignment interval, and
the pipe connects more than one of the evaporators to one of the condensers.

18. The electronic device using the cooling structure for an electronic circuit board according to claim 5, comprising a plurality of the evaporators, and a plurality of the condensers comprising at least a first condenser and a second condenser,
wherein the second condenser is disposed to be an extension of a straight line connecting one of the evaporators to the first condenser.

19. The electronic device using the cooling structure for an electronic circuit board according to claim 6, comprising a plurality of the evaporators, and a plurality of the condensers comprising at least a first condenser and a second condenser,
wherein the second condenser is disposed to be an extension of a straight line connecting one of the evaporators to the first condenser.

20. The electronic device using the cooling structure for an electronic circuit board according to claim 5,
wherein an upper end of the condenser in the vertical direction is above the level of an upper end of the electronic circuit board in the vertical direction, in the arrangement state that the drawing direction of the flow path plates is nearly parallel to the vertical direction.
